(19) United States
(12) Patent Application Publication
(10) Pub. No.: US 2025/0142849 A1
(43) Pub. Date: May 1, 2025

(54) Capacitor structure with fin structure and manufacturing method thereof

(71) Applicant: UNITED MICROELECTRONICS cORP., Hsin-Chu City (TW)

(72) Inventors: Hsin-Hsien Chen, New Taipei City (TW); Kuo-Hsing Lee, Hsinchu County (TW); Chih-Kai Kang, Tainan City (TW); Sheng-Yuan Hsueh, Tainan City (TW)

(73) Assignee: UNITED MICROELECTRONICS CORP., Hsin-Chu City (TW)

(21) Appl. No.: 18/513,657

(22) Filed: Nov. 20, 2023

(30) Foreign Application Priority Data
Oct. 25, 2023 (TW) 112140749

(51) Int. Cl. H01L 27/06

(52) U.S. Cl. CPC H10D 1/716; H10D 84/811

(57) ABSTRACT

The invention provides a capacitor structure with a fin structure, which comprises a fin structure located on a substrate, a lower electrode layer, a high dielectric constant layer and an upper electrode layer stacked on the fin structure in sequence, and an ion doped region located in the substrate below the fin structure, and a top surface of the ion doped region is aligned with a bottom surface of the fin structure.

### BACKGROUND OF THE INVENTION

### 1. Field of the Invention

The invention relates to the field of semiconductor manufacturing, in particular to a capacitor structure with fin structure and a manufacturing method thereof, which has high manufacturing yield.

### 2. Description of the Prior Art

At present, in the process of semiconductor integrated circuits, most of them still use the traditional flat capacitor to connect to a semiconductor metal oxide (MOS) transistor to form a memory device. The traditional flat capacitor consists of a lower electrode plate, a capacitor dielectric layer and an upper electrode plate, which not only needs three masks to define the patterns of each layer, but also takes up a huge chip area to meet the design capacitor requirements. Therefore, how to reduce the space required to define the capacitor structure on the die (that is, increase the capacitor density), improve the device integration, reduce the number of masks used, and reduce the production cost has become one of the research and development focuses when manufacturing the capacitor structure.

In order to improve the density of capacitors, fin structures are integrated into capacitor structures in the current technology to form a three-dimensional capacitor structure. Please refer to FIG. 1, which shows a schematic cross-sectional view of a conventional three-dimensional capacitor structure. As shown in FIG. 1, a substrate 10 is provided, and the substrate 10 includes a fin structure F, the material of the fin structure F is the same as that of the substrate 10, such as silicon. Then, the fin structure F is ion doped, and a doped region 11 is formed in the fin structure F to reduce the resistance of the fin structure F, so that the fin structure F can be used as the lower electrode of the capacitor formed subsequently. Subsequently, an insulating layer 12 (e.g., silicon oxide, which can be formed by thermal oxidation process) and an upper electrode layer 14 are sequentially formed on the fin structure, the upper electrode layer 14 may include a work function metal layer and a conductive layer. Therefore, the upper electrode 14, the insulating layer 12 and the doped fin structure F (as the lower electrode) can form a three-dimensional capacitor structure.

However, in the actual manufacturing process, after doping ions into the fin structure F, an annealing step will be performed to make the doped ions uniformly diffuse into the entire fin structure F. However, the applicant found that some specific kinds of doping ions combined with annealing steps would damage the fin structure F. Please refer to FIG. 2, which shows a schematic cross-sectional view of a conventional three-dimensional capacitor structure after annealing. As shown in FIG. 2, if the ion species doped in the fin structure F is arsenic (As) or phosphorus (P), it is easy to corrode the fin structure F after the annealing step, and the shape of the fin structure F may be changed (for example, the top surface of the fin structure F is sharpened as shown in FIG. 2). This is not conducive to the quality of the capacitor structure and may increase the leakage current of the capacitor structure.

Therefore, it is necessary to study a capacitor structure to solve the above problems.

### SUMMARY OF THE INVENTION

The invention provides a capacitor structure with a fin structure, which comprises a fin structure located on a substrate, a lower electrode layer, a high dielectric constant layer and an upper electrode layer stacked on the fin structure in sequence, and an ion doped region located in the substrate below the fin structure, and a top surface of the ion doped region is aligned with a bottom surface of the fin structure.

The invention also provides a method for forming a capacitor structure comprising a fin structure, which comprises forming a fin structure on a substrate, forming a lower electrode layer, a high dielectric constant layer and an upper electrode layer stacked on the fin structure in sequence, and forming an ion doped region in the substrate below the fin structure, a top surface of the ion doped region is aligned with a bottom surface of the fin structure.

The invention is characterized by providing a three-dimensional capacitor structure comprising a fin structure, a three-layer structure such as a lower electrode layer, a dielectric layer and an upper electrode layer is directly formed on the fin structure, so that a three-dimensional capacitor structure can be manufactured. In addition, in order to reduce the damage of ions to the fin structure, the ion doping region is arranged in the substrate below the fin structure, and the ion doping concentration in the fin structure is unevenly distributed (the closer to the upper part, the lower the ion concentration). The lower electrode of the capacitor is connected to the lower electrode contact structure through the ion doping region and the epitaxial layer, and the upper electrode contact structure and the lower electrode layer do not overlap each other in the cross section, so that the process difficulty can be reduced and the yield can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic cross-sectional view of a conventional three-dimensional capacitor structure.

FIG. 2 shows a schematic cross-sectional view of a conventional three-dimensional capacitor structure after annealing.

FIG. 3 shows a top view of a capacitor structure with a fin structure and a transistor structure according to the first preferred embodiment of the present invention.

FIG. 4 is a schematic view of the cross-sectional structure taken along section line A-A′ and section line B-B′ in FIG. 3.

FIG. 5 is a schematic cross-sectional view showing the structure of FIG. 4, and the conductive layer and contact structures are formed continuously.

FIG. 6 is a schematic sectional view of another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

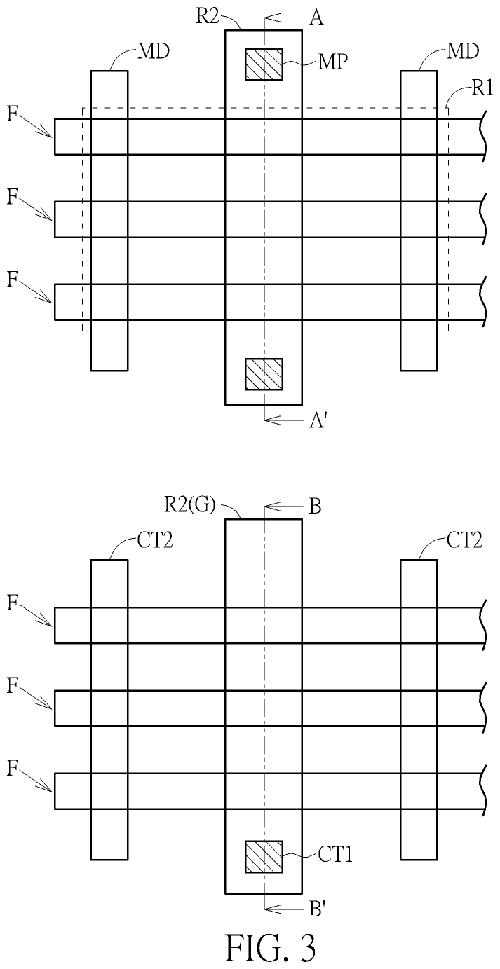

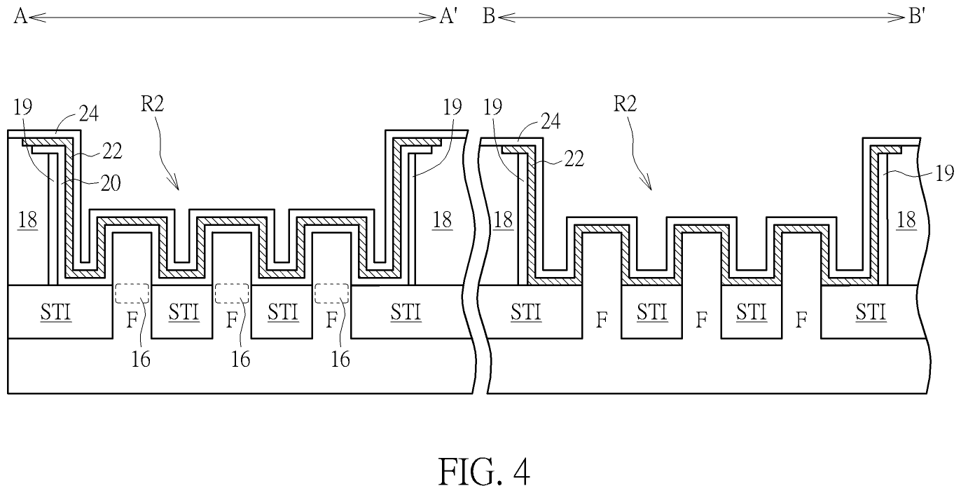

FIG. 3 shows a top view of a capacitor structure including a fin structure and a transistor structure according to the first preferred embodiment of the present invention, and FIG. 4 shows a schematic view of the cross-sectional structure taken along section line A-A′ and section line B-B′ in FIG. 3. As shown in FIGS. 3 and 4, the left half of the figure shows the top view and cross section of a capacitor structure, while the right half shows the top view and cross section of a transistor structure. In the present invention, the capacitor structure can be integrated into the process of transistor structure, that is to say, some processes of the two will be similar or the same. Therefore, it is possible to form a transistor structure and a capacitor structure at the same time.

It is worth noting that both the capacitor structure and the transistor structure depicted in FIG. 3 are located on the substrate 10, and they may be adjacent to each other or located in different regions with a long distance. Or in some embodiments, the transistor region may not be formed, and the above variations are within the scope of the present invention.

As shown in FIGS. 3 and 4, a substrate 10 includes a plurality of fin structures F, and shallow trench isolation STI is located beside the fin structures F on the substrate 10. Among them, the substrate 10 and the fin structure F are made of silicon, and the shallow trench isolation STI is made of silicon oxide, but not limited to this. Next, a region R1 is defined on the substrate 10, and an ion doping step is performed in the region R1 to dope ions such as arsenic (As) or phosphorus (P) into the substrate 10, especially into part of the fin structure F, but the ions are only doped in the region R1 of the capacitor structure (left half) and not into the fin structure F in the transistor structure (right half). It is worth noting that, as shown in FIG. 4, in order to avoid the situation that arsenic (As) or phosphorus (P) ions will damage the fin structure F after the doping and annealing steps in the prior art, this embodiment controls the depth of the ion doping step so that the ion doped region 16 after the doping step is formed below the fin structure F, preferably in the substrate 10 below the fin structure F, rather than in the fin structure F. More preferably, the top surface of the ion doped region 16 is aligned with the bottom surface of the fin structure F (i.e., the top surface of the substrate 10 in FIG. 4), and the doped ions include arsenic (As) or phosphorus (P) ions.

In addition, after the fin structure F is formed on the substrate 10, a polysilicon gate (not shown) and a dielectric layer 18 are formed to cover the substrate 10, and after the polysilicon gate is removed, a groove defined by the dielectric layer 18 is left (i.e., the region R2 or the position of the gate G in FIG. 3). Subsequently, some material layers needed for the capacitor structure such as the lower electrode, the insulating layer and the upper electrode will be formed in the groove.

In addition, after the polysilicon gate is completed, an epitaxial process can be formed on the surface of the fin structure F, and an epitaxial layer such as SiGe or SiP can be formed on the surface of the fin structure F. The epitaxial layer formed here is used to connect the subsequently formed lower electrode with the contact structure. According to FIG. 3, the epitaxial layer should be formed on the surface of the fin structure F except the range of the gate G, but it is not drawn for the sake of simplicity.

Within the range of the groove R2, spacers 19 can be formed to cover the sidewall of the groove R2. The purpose of forming the spacers 19 is to protect the inner sidewall surface of the groove R2, and at the same time, the lower electrode layer formed subsequently will cover the spacers 19, so the adhesion between the lower electrode layer and the spacers 19 can be improved if the spacer 19 is made of an appropriate material. In this embodiment, the material of the spacer 19 may include silicon oxide, silicon nitride or silicon oxynitride, but it is not limited thereto.

Next, referring to FIGS. 3 and 4, the lower electrode layer 20, the dielectric layer 22 and the upper electrode layer 24 are formed in the groove R2 in the capacitor structure (left half), and the dielectric layer 22 and the upper electrode layer 24 are formed in the transistor structure (right half). The materials of the lower electrode layer 20 and the upper electrode layer 24 are, for example, titanium nitride (TiN) or tantalum nitride (TaN), but are not limited to this, and other kinds of metal layers or work function metal layers can also be suitable for manufacturing the lower electrode layer 20 and the upper electrode layer 24 of the present invention. The dielectric layer 22 comprises, for example, a layer with a high dielectric constant, including silicon oxide (SiO), silicon nitride (SiN), silicon oxynitride (SiON), or a dielectric material with a dielectric constant greater than 4, such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃, zirconium silicon oxide (ZrSiO₄), hafnium zirconium oxide (HfZrO₄), strontium bismuth tantalate (SrBi₂Ta₂O₉, SBT), lead zirconate titanate (PbZrxTi₁₋ₓO₃, PZT), barium strontium titanate (BaxSr₁₋ₓTiO₃, BST) or a combination thereof.

In the present invention, the capacitor structure comprises a lower electrode layer 20, a dielectric layer 22 and an upper electrode layer 24, so the three layers constitute the capacitor structure. As for the dielectric layer 22 included in the transistor structure, it can be used as the gate dielectric layer, and the upper electrode layer 24 can be used as the work function layer or barrier layer of the gate to be formed later. The transistor structure does not include the lower electrode layer 20.

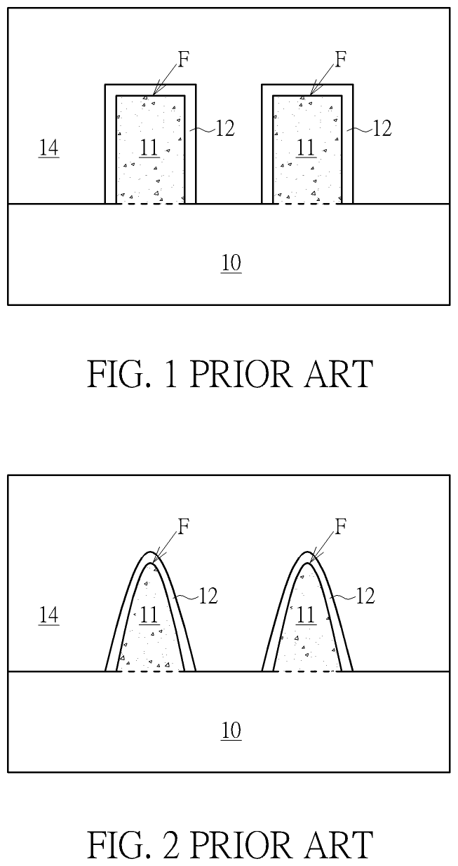

It is worth noting that, compared with the conventional three-dimensional capacitor structure shown in FIG. 1 or FIG. 2, the ion doped region 16 of this embodiment is formed in the substrate 10 below the fin structure F, so after the annealing step, the ion concentration decreases from the center region of the ion doped region 16 to the outside region and presents a Gaussian distribution, and only a small amount of ions will diffuse into the fin structure F. Therefore, the problem of ion destroying the fin structure as shown in FIG. 2 does not occur. In other words, in this embodiment, the doping depth of ions is controlled during the doping step, so that the ion doping region 16 is far away from the top surface of the fin structure F, so that the damage of arsenic ions or phosphorus ions to the fin structure F can be reduced after the annealing step.

In addition, in the conventional three-dimensional capacitor structure shown in FIG. 1 or FIG. 2, the body of the fin structure F doped with ions is used as the lower electrode of the capacitor structure. However, in this embodiment, in order to prevent the fin structure F from being damaged by ions, ions are not doped into the complete fin structure, and an additional lower electrode layer 20 is formed to be used as the lower electrode of the capacitor structure. Therefore, in the structure of this embodiment, the lower electrode layer 20, the dielectric layer 22 and the upper electrode layer 24 are still included above the fin structure F, instead of only the insulating layer 12 and the upper electrode 14 located on the fin structure F as shown in FIGS. 1 and 2.

In addition, in the capacitor structure in FIG. 3 (left half), a lower electrode contact structure MD and an upper electrode contact structure MP are separately formed, the upper electrode contact structure MP is located in the range of the groove R2 (that is, the original polysilicon gate forming position) for electrically connecting the upper electrode layer 24 of the capacitor structure, while the lower electrode contact structure MD is formed on the fin structure F for electrically connecting the epitaxial layer with the ion doped region 16, and then electrically connected with the lower electrode layer 20. In other words, the upper electrode and the lower electrode of the capacitor structure are electrically connected with the upper electrode contact structure MP and the lower electrode contact structure MD respectively. As for the transistor structure (right half), the contact structure CT1 is similar to the upper electrode contact structure MP, but it is used to connect the gate G of the transistor, while the contact structure CT2 is similar to the lower electrode contact structure MD, but it is used to connect the source/drain of the transistor.

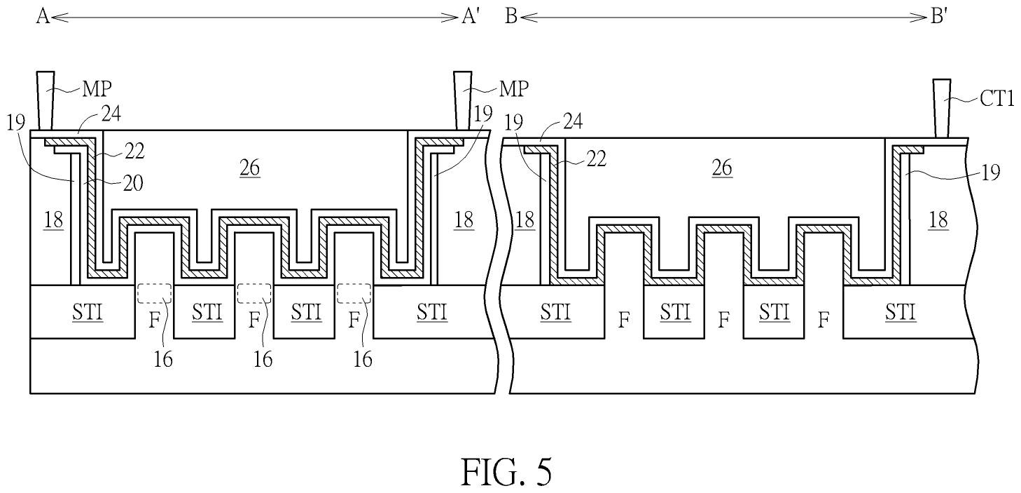

FIG. 5 is a schematic cross-sectional view showing the structure of FIG. 4, and the conductive layer and contact structures are formed continuously. As shown in FIG. 5, from the cross section, the conductive layer 26, such as tungsten, can be formed and filled in the groove R2, and the conductive layer 26 can be used as the gate structure of the transistor. In addition, the upper electrode contact structure MP is located directly above the upper electrode layer 24, but neither the dielectric layer 22 nor the lower electrode layer 20 is located directly below the upper electrode contact structure MP. As mentioned above, the lower electrode layer 20 is electrically connected with the epitaxial layer through the ion doped region 16, so it is not necessary to form a contact structure above the capacitor structure to electrically connect the lower electrode layer 20. In other words, in this embodiment, the upper electrode contact structure MP (that is, the contact structure electrically connected to the upper electrode layer 24) and the lower electrode layer 20 do not overlap each other in cross section, so that it can be avoided that the contact structure MP will not touch the lower electrode layer 20 when it erodes through the upper electrode layer 24 due to excessive etching. This can improve the stability and yield of the process.

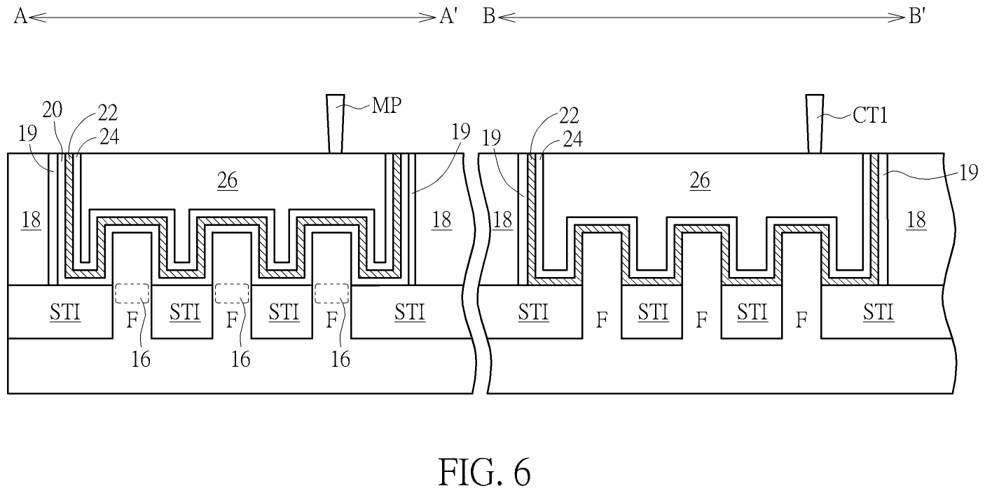

FIG. 6 shows a schematic cross-sectional structure of another embodiment of the present invention, in which most of the structures are similar to those of FIG. 5, so repeated parts are not repeated here. The characteristic of this embodiment is that after the upper electrode layer 24 and the conductive layer 26 are completed, a planarization step can be performed to remove the redundant material layer, and the subsequently formed upper electrode contact structure MP and contact structure CT1 directly contact the conductive layer 26. Because of the planarization step, the top surface of the conductive layer 26 of the capacitor structure (left half) and the top surface of the transistor structure (right half) are aligned with each other. This embodiment is also within the scope of the present invention.

Based on the above description and drawings, the present invention provides a capacitor structure with a fin structure, which comprises a fin structure F located on a substrate 10, a lower electrode layer 20, a high dielectric constant layer (dielectric layer 22) and an upper electrode layer 24 stacked on the fin structure F in sequence, and an ion doped region 16 located in the substrate 10 below the fin structure F, and a top surface of the ion doped region 16 is aligned with a bottom surface of the fin structure F.

The invention further provides a method for forming a capacitor structure with a fin structure F, the method includes forming a fin structure F on a substrate 10, forming a lower electrode layer 20, a high dielectric constant layer 22 and an upper electrode layer 24 sequentially stacked on the fin structure F, and forming an ion doped region 16 in the substrate 10 below the fin structure F, and a top surface of the ion doped region 16 is aligned with a bottom surface of the fin structure F.

In some embodiments of the present invention, the concentration of the ion doped region 16 decreases from a center region to an outside region.

In some embodiments of the present invention, the concentration of the ion doped region 16 exhibits a Gaussian distribution.

In some embodiments of the present invention, a dielectric layer 18 is located on the substrate 10, and the dielectric layer 18 defines a groove R2, and part of the fin structure F is located in the groove R2.

In some embodiments of the present invention, the lower electrode layer 20 covers at least a top surface of the dielectric layer 18, a top surface of the substrate 10, a top surface and a sidewall of the fin structure F (refer to FIG. 4).

In some embodiments of the present invention, a spacer 19 is further included, which is located on a sidewall of the groove R2, and the lower electrode layer 20 covers the spacer 19.

In some embodiments of the present invention, the lower electrode layer 20, the high dielectric constant layer 22 and the upper electrode layer 24 have the same cross-sectional profile (all formed along the cross-sectional profile of the fin structure F).

In some embodiments of the present invention, an upper electrode contact structure MP is further included, which is electrically connected to the upper electrode layer 24, wherein the lower electrode layer 20 is not located directly below the upper electrode contact structure MP.

In some embodiments of the present invention, the doping ions in the ion doped region 16 include phosphorus ions and arsenic ions.

In some embodiments of the present invention, the lower electrode contact structure MD is located on the fin structure F, and the lower electrode contact structure MD is electrically connected to the lower electrode layer 20 through the ion doped region 16.

The invention is characterized by providing a three-dimensional capacitor structure comprising a fin structure, a three-layer structure such as a lower electrode layer, a dielectric layer and an upper electrode layer is directly formed on the fin structure, so that a three-dimensional capacitor structure can be manufactured. In addition, in order to reduce the damage of ions to the fin structure, the ion doping region is arranged in the substrate below the fin structure, and the ion doping concentration in the fin structure is unevenly distributed (the closer to the upper part, the lower the ion concentration). The lower electrode of the capacitor is connected to the lower electrode contact structure through the ion doping region and the epitaxial layer, and the upper electrode contact structure and the lower electrode layer do not overlap each other in the cross section, so that the process difficulty can be reduced and the yield can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor structure with a fin structure, comprising:
a fin structure located on a substrate;
a lower electrode layer, a high dielectric constant layer and an upper electrode layer sequentially stacked on the fin structure; and
an ion doped region located in the substrate below the fin structure, and a top surface of the ion doped region is aligned with a bottom surface of the fin structure.

2. The capacitor structure with a fin structure according to claim 1, wherein the concentration of the ion doped region decreases from a center region to an outside region.

3. The capacitor structure with a fin structure according to claim 1, wherein the concentration of the ion doped region presents Gaussian distribution.

4. The capacitor structure with a fin structure according to claim 1, further comprising a dielectric layer located on the substrate, and the dielectric layer defines a groove, and part of the fin structure is located in the groove.

5. The capacitor structure with a fin structure according to claim 4, wherein the lower electrode layer at least covers a top surface of the dielectric layer, a top surface of the substrate, a top surface and a sidewall of the fin structure.

6. The capacitor structure with a fin structure according to claim 5, further comprising a spacer located on a sidewall of the groove, and the lower electrode layer covers the spacer.

7. The capacitor structure with a fin structure according to claim 1, wherein the lower electrode layer, the high dielectric constant layer and the upper electrode layer have the same cross-sectional profile from a cross-sectional view.

8. The capacitor structure with a fin structure according to claim 1, further comprising an upper electrode contact structure electrically connected to the upper electrode layer, wherein the lower electrode layer is not located directly below the upper electrode contact structure.

9. The capacitor structure with a fin structure according to claim 1, wherein the doped ions in the ion doped region include phosphorus ions and arsenic ions.

10. The capacitor structure with a fin structure according to claim 1, further comprising a lower electrode contact structure located on the fin structure, and the lower electrode contact structure is electrically connected to the lower electrode layer through the ion doped region.

11. A method for forming a capacitor structure with a fin structure, comprising:
forming a fin structure on a substrate;
forming a lower electrode layer, a high dielectric constant layer and an upper electrode layer sequentially stacked on the fin structure; and
forming an ion doped region in the substrate below the fin structure, and a top surface of the ion doped region is aligned with a bottom surface of the fin structure.

12. The method for forming a capacitor structure with a fin structure according to claim 11, wherein the concentration of the ion doped region decreases from a center region to an outside region.

13. The method for forming a capacitor structure with a fin structure according to claim 11, wherein the concentration of the ion doped region presents Gaussian distribution.

14. The method for forming a capacitor structure with fin structure according to claim 11, further comprising forming a dielectric layer on the substrate, and the dielectric layer defines a groove, and part of the fin structure is located in the groove.

15. The method for forming a capacitor structure with a fin structure according to claim 14, wherein the lower electrode layer covers at least a top surface of the dielectric layer, a top surface of the substrate, a top surface and a sidewall of the fin structure.

16. The method for forming a capacitor structure with fin structure according to claim 15, further comprising forming a spacer located on a sidewall of the groove, and the lower electrode layer covering the spacer.

17. The method for forming a capacitor structure with a fin structure according to claim 11, wherein the lower electrode layer, the high dielectric constant layer and the upper electrode layer have the same cross-sectional profile from a cross-sectional view.

18. The method for forming a capacitor structure with a fin structure according to claim 11, further comprising forming an upper electrode contact structure electrically connected to the upper electrode layer, wherein the lower electrode layer is not located directly below the upper electrode contact structure.

19. The method for forming a capacitor structure with a fin structure according to claim 11, wherein the doped ions in the ion doped region comprises phosphorus ions and arsenic ions.

20. The method for forming a capacitor structure with a fin structure according to claim 11, further comprising forming a lower electrode contact structure on the fin structure, and the lower electrode contact structure is electrically connected with the lower electrode layer through the ion doped region.
